(19) United States
(12) Patent Application Publication
(10) Pub. No.: US 2019/0206827 A1
(43) Pub. Date: Jul. 4, 2019

(54) SEMICONDUCTOR PACKAGE WITH EXTERNALLY ACCESSIBLE WIREBONDS

(71) Applicant: Intel Corporation, Santa Clara, CA (US)

(72) Inventor: HANY ESKANDAR, Folsom, CA (US)

(73) Assignee: Intel Corporation, Santa Clara, CA (US)

(21) Appl. No.: 15/857,888

(22) Filed: Dec. 29, 2017

(51) Int. Cl. H01L 23/00; H01L 23/31; H01L 23/498; H01L 25/10; H01L 21/56; H01L 25/065

(52) U.S. Cl. CPC H01L 24/49; H01L 2924/14; H01L 23/49816; H01L 24/05; H01L 24/09; H01L 25/105; H01L 24/17; H01L 21/565; H01L 25/0655; H01L 25/0657; H01L 24/11; H01L 24/73; H01L 2224/0401; H01L 2224/04042; H01L 2224/17104; H01L 2224/32145; H01L 2224/48091; H01L 2224/48145; H01L 2224/48227; H01L 2224/48463; H01L 2224/49113; H01L 2924/15311; H01L 23/3128

(57) ABSTRACT

A semiconductor package includes test pad stack disposed in a first region of an upper surface of a semiconductor package substrate. One or more semiconductor dies conductively couple to the test pad stack. A first end of a test wirebond conductively couples to the test pad stack. A dummy pad stack is disposed in a peripheral region on the upper surface of the semiconductor package substrate. A second end of the test wirebond conductively couples to the dummy pad stack. A mold compound disposed on, about, or across the first region and the peripheral regions of the upper surface of the semiconductor package substrate at least partially covering the semiconductor die stack. A first portion of the test wirebond is disposed in the cured mold compound. The peripheral regions may be trimmed from the semiconductor package substrate, exposing at least a second portion of the test wirebond.

### TECHNICAL FIELD

The present disclosure relates to semiconductor packaging.

### BACKGROUND

Semiconductor packages include one or more semiconductor dies coupled to a semiconductor package substrate. The one or more semiconductor dies are protected by overmolding with a mold compound that isolates at least a portion of the semiconductor die from the ambient environment. The one or more semiconductor dies couple to external circuits using a plurality of contact pads on the bottom surface of the semiconductor package. Typically solder balls or bumps are attached each of the contact pads. Thus, access to the one or more semiconductor dies in the semiconductor package is limited to access through contact pads or through the solder balls used in the ball grid array on the bottom of the semiconductor package. Direct access to the some or all of the one or more semiconductor dies, for example for test purposes, may not be possible due to the semiconductor package substrate disposed between the contact pad and the semiconductor dies. Furthermore, once the semiconductor package is coupled to the motherboard access to either the solder balls or the contact pads may be difficult or even impossible.

### BRIEF DESCRIPTION OF THE DRAWINGS

Features and advantages of various embodiments of the claimed subject matter will become apparent as the following Detailed Description proceeds, and upon reference to the Drawings, wherein like numerals designate like parts, and in which:

FIG. 1 is a schematic of an illustrative system that includes a semiconductor package that includes a plurality of test wirebond connections operably coupled to a motherboard via a plurality of conductive structures, in accordance with at least one embodiment described herein;

FIG. 2A is a cross-sectional elevation of an illustrative semiconductor package that includes a plurality of stacked semiconductor dies disposed on a semiconductor package substrate that includes a first region occupied by the semiconductor die stack and one or more peripheral regions, in accordance with at least one embodiment described herein;

FIG. 2B is a cross sectional elevation of the illustrative semiconductor package in FIG. 2A with pad stacks disposed on the first portion of the upper surface of the semiconductor package substrate and dummy pad stacks disposed in the peripheral region of the upper surface of the semiconductor package substrate, in accordance with at least one embodiment described herein;

FIG. 2C is a cross sectional elevation of the illustrative semiconductor package in FIG. 2B with test wirebond conductively coupling pad stack to dummy pad stack and test wirebond conductively coupling pad stack to dummy pad stack, in accordance with at least one embodiment described herein;

FIG. 2D is a cross sectional elevation of the illustrative semiconductor package in FIG. 2C with a mold compound disposed across the upper surface of the semiconductor package substrate, in accordance with at least one embodiment described herein;

FIG. 2E is a cross sectional elevation of the illustrative semiconductor package in FIG. 2D depicting cut lines to remove the peripheral regions of the semiconductor package substrate, in accordance with at least one embodiment described herein;

FIG. 2F is a cross sectional elevation of the illustrative semiconductor package in FIG. 2E after removing the peripheral regions of the semiconductor package substrate and exposing the test wirebonds, in accordance with at least one embodiment described herein;

FIG. 2G is a cross sectional elevation of the illustrative semiconductor package in FIG. 2F after forming the cavities about the test wirebonds, in accordance with at least one embodiment described herein;

FIG. 2H is a cross sectional elevation of the illustrative semiconductor package in FIG. 2G after filling the cavities with a filler material, in accordance with at least one embodiment described herein;

FIG. 3A is a cross-sectional elevation of an illustrative semiconductor package that includes a plurality of stacked semiconductor dies disposed on a semiconductor package substrate that includes a first region occupied by the semiconductor die stack and one or more peripheral regions, in accordance with at least one embodiment described herein;

FIG. 3B is a cross sectional elevation of the illustrative semiconductor package depicted in FIG. 3A depicting cut lines and cavities disposed on an upper surface of the semiconductor package, in accordance with at least one embodiment described herein;

FIG. 3C is a cross sectional elevation of the illustrative semiconductor package in FIG. 3B with test wirebonds conductively coupled to a stacked second semiconductor package via solder balls, in accordance with at least one embodiment described herein;

FIG. 4 is a schematic diagram of an illustrative processor-based device that includes a system-in-chip having test wirebonds, as described in FIGS. 1 through 3 and in accordance with at least one embodiment described herein;

FIG. 5 is a high-level flow diagram of an illustrative method of fabricating a semiconductor package having at least one externally accessible test wirebond, in accordance with at least one embodiment described herein; and

FIG. 6 is a high-level flow diagram of an illustrative method of fabricating a semiconductor package having at least one externally accessible test wirebond, in accordance with at least one embodiment described herein.

Although the following Detailed Description will proceed with reference being made to illustrative embodiments, many alternatives, modifications and variations thereof will be apparent to those skilled in the art.

### DETAILED DESCRIPTION

The systems and methods described herein beneficially and advantageously provide access to semiconductor dies within an overmolded semiconductor package without requiring access to the solder balls and/or contact pads on the lower surface of the semiconductor package. Instead, access to the semiconductor die is provided by conductively coupling a test wirebond to a dummy pad stack on the upper surface of the semiconductor package substrate. The semiconductor die may be directly coupled to the dummy pad stack, for example via a wirebond. The semiconductor die may be indirectly coupled to the dummy pad stack, for example via circuitry disposed in the semiconductor package substrate. The test wirebond is routed through the mold compound to an external surface (i.e., side or top) of the overmolded semiconductor package.

A cavity may be formed in the external surface of the semiconductor package proximate the location of the test wirebond to facilitate the temporary communicable coupling of an external instrument, such as a test probe, to the test wirebond. For example, a cavity may be formed on an external sidewall of the semiconductor package to facilitate the coupling of a test probe to the test wirebond. In such instances, the cavity may be filled with an electrically non-conductive, dielectric, or insulative material after disconnection of the external instrument.

In other instances, a cavity may be formed in the external surface of the semiconductor package proximate the location of the test wirebond to facilitate the communicable coupling of an external device, such as a second semiconductor die, to the test wirebond. In such instances, an electrically conductive material, such as a solder ball, may be disposed in the cavity prior to reflow to provide a permanent conductive coupling to an external device. For example, a cavity may be formed on the top or upper surface of a semiconductor package, a solder ball may be disposed at least partially in the cavity and a second semiconductor die may be stacked such that the solder ball falls proximate a contact pad on the second semiconductor die. During reflow, the solder ball may communicably couple the test wirebond to the second semiconductor die contact pad.

As used herein the terms “top,” “bottom,” “upper,” “lower,” “lowermost,” and “uppermost” when used in relationship to one or more elements are intended to convey a relative rather than absolute physical configuration. Thus, an element described as an “upper film layer” or a “top element” in a device may instead form the “lowermost element” or “bottom element” in the device when the device is inverted. Similarly, an element described as the “lowermost element” or “bottom element” in the device may instead form the “uppermost element” or “top element” in the device when the device is inverted.

As used herein, the term “logically associated” when used in reference to a number of objects, systems, or elements, is intended to convey the existence of a relationship between the objects, systems, or elements such that access to one object, system, or element exposes the remaining objects, systems, or elements having a “logical association” with or to the accessed object, system, or element. An example “logical association” exists between relational databases where access to an element in a first database may provide information and/or data from one or more elements in a number of additional databases, each having an identified relationship to the accessed element. In another example, if “A” is logically associated with “B,” accessing “A” will expose or otherwise draw information and/or data from “B,” and vice-versa.

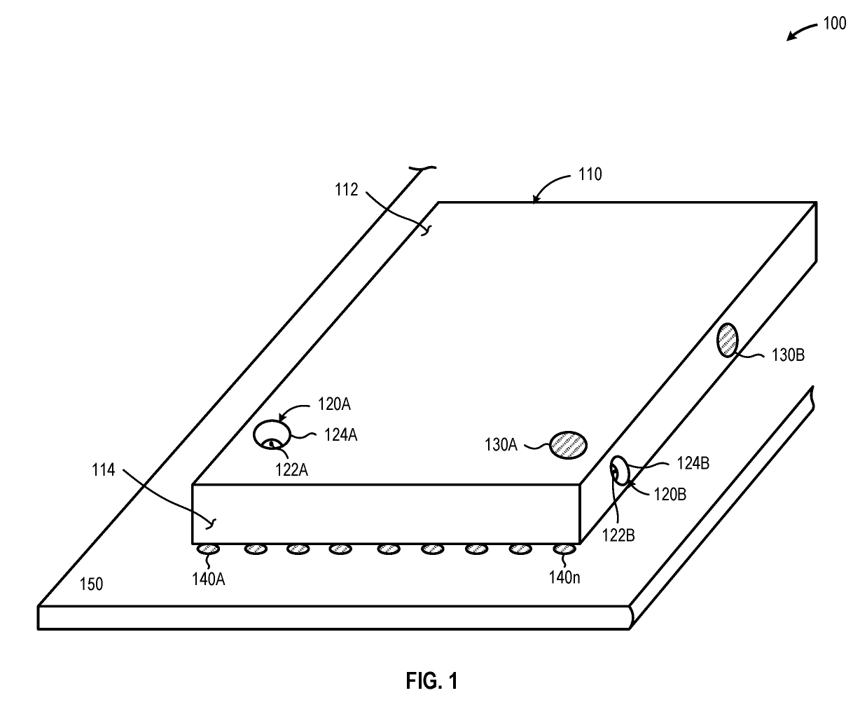

FIG. 1 is a schematic of an illustrative system 100 that includes a semiconductor package 110 that includes a plurality of test wirebond connections 120A, 120B (collectively, “test wirebond connections 120”) operably coupled to a motherboard 150 via a plurality of conductive structures 140A-140n (collectively, “conductive structures 140”), in accordance with at least one embodiment described herein. In embodiments, each of the test wirebond connections 120A, 120B includes a respective test wirebond 122A, 122B (collectively, “test wirebonds 122”) disposed in a respective cavity 124A, 124B (collectively, “cavities 124”) that is formed in an exterior surface of the semiconductor package 110, such as on the top 112 or side 114 of the semiconductor package 110. In embodiments, the test wirebond connections 120 permit the conductive coupling of external devices to some or all of the semiconductor dies disposed within the semiconductor package 110 for testing, quality control, and/or diagnostic purposes. After completion of the testing, quality control or diagnostic procedures, the cavity 124 may be filled with a filler material 130A, 130B (collectively, “filler materials 130”) to protect the exposed test wirebonds 122 from damage and also to protect the semiconductor dies conductively coupled to the test wirebonds 122 from damage. In embodiments, the filler material 130 may include one or more electrically non-conductive or dielectric materials that at least partially fill the cavity 124. In other embodiments, the filler material 130 may include one or more electrically conductive materials that at least partially fill the cavity 124.

The semiconductor package 110 may be operably coupled to a substrate 150, such as a motherboard or similar. In embodiments, the semiconductor package 110 may be communicably coupled to the substrate 150 using the plurality of conductive structures 140. In embodiments, the semiconductor package 110 may include a plurality of contact pads disposed in, on, about or across the lower surface of the semiconductor package 110 (not visible in FIG. 1). In such embodiments, the conductive structures 140 may include a plurality of solder bumps or solder balls that are coupled to at least some of the plurality of contact pads. The solder balls or bumps may be melted, for example during a reflow operation, to operably and conductively couple the semiconductor package 110 to the substrate 150.

The semiconductor package 110 may include one or more partially or completely overmolded semiconductor dies. In embodiments, the semiconductor package 110 may include, but is not limited to, any type of semiconductor package, such as: a System-in-Package (SiP); a System-on-a-Chip (SoC); a stacked die semiconductor; an exposed die semiconductor; or any other type of fully are partially overmolded semiconductor package. In embodiments, the semiconductor package 110 may include a ball grid array (BGA) package that includes a plurality of contact pads disposed on the lower surface of the semiconductor package. Conductive structures 140, such as solder balls and/or bumps, may be disposed proximate some or all of the contact pads. Once reflowed, the conductive structures 140 may physically and/or communicably couple the semiconductor package 110 to the substrate 150.

In a completely overmolded semiconductor package, access to individual semiconductor dies within the package is limited or impossible. The test wirebond connections 120 beneficially and advantageously provide access to individual semiconductor dies within an overmolded semiconductor package 110. A first portion of the test wirebond 122 extends through the semiconductor package overmold and conductively couples to a semiconductor die within the semiconductor package 110. A second portion of the test wirebond 122 remains exposed within the cavity 124, permitting the communicable coupling of another device, such as test equipment, electrical component, or second semiconductor package, to the semiconductor die. The test wirebond 122 includes a member fabricated using one or more conductive materials, such as copper, a copper-containing alloy, silver, a silver-containing alloy, gold, a gold-containing alloy, or any other single or combination of electrically conductive metallic or non-metallic members.

A cavity 124 at least partially surrounds the test wirebond 122. In embodiments, the cavity 124 may be formed using a mechanical material removal process or method, such as by drilling or abrasion. In other embodiments, the cavity 124 may be formed by laser ablation. In embodiments, the cavity 124 may include a hemispherical or conical void space having sloped or tapered sidewalls. In embodiments, the test wirebond 122 may be exposed approximately in the center and/or “bottom” of the cavity 124. The formation of the cavity 124 beneficially and advantageously permits the temporary communicable coupling of an external device to the test wirebond 122 after the semiconductor package 110 is operably coupled to the substrate 150. In embodiments, the sloped and/or tapered surfaces of the cavity 124 beneficially and advantageously cause a probe or similar electrically conductive member to travel to a point proximate the test wirebond 122.

The exposed test wirebonds 122 beneficially provide access to the semiconductor dies within the semiconductor package 110 even after the semiconductor package 110 is coupled to the substrate 150. However, the exposed test wirebonds can be prone to chemical attack from environmental contaminants and/or shorting by electrically conductive environmental contaminants. To reduce the likelihood of such attacks from environmental contaminants, one or more filler materials 130 may be disposed in the cavity 124 to seal the exposed second portion of the test wirebond 122. In embodiments, the one or more filler materials 130 may completely fill the cavity 124. In other embodiments, the one or more filler materials 130 may at least partially fill the cavity 124.

In embodiments, the filler material 130 may include any number and/or combination of electrically insulative or dielectric materials. For example, the filler material 130 may include an epoxy or similar material. In other embodiments, the one or more filler materials 130 may include any number and/or combination of electrically conductive materials, such as an electrically conductive polymer (e.g., indium tin oxide, conductive nanoparticles in a polymer matrix), solder, solder balls, or similar. Disposing an electrically conductive filler 130 in the cavity 124 permits the subsequent conductive and/or communicable coupling of an external device such as a second semiconductor package or other electrical devices and/or components to the semiconductor die included in the semiconductor package 110.

A plurality of conductive structures 140 conductively and/or communicably couple the semiconductor package 110 to the substrate 150. In embodiments, the plurality of conductive structures 140 may include, but are not limited to, a plurality of solder bumps, a plurality of solder balls, or similar. In embodiments, the plurality of conductive structures 140 may include a plurality of spring loaded, electrically conductive, structures that may be compressed against contact pads formed on the surface of the substrate 150. The substrate 150 may include any number and/or combination of members suitable for the attachment of the semiconductor package 110. Non-limiting examples of substrates 150 include: a motherboard, a daughterboard, and similar.

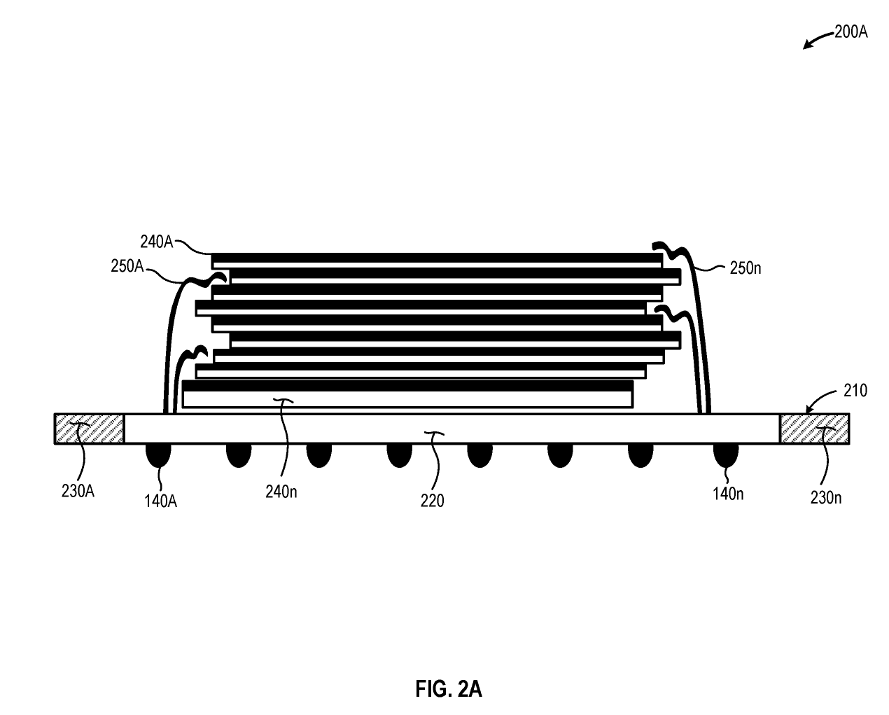

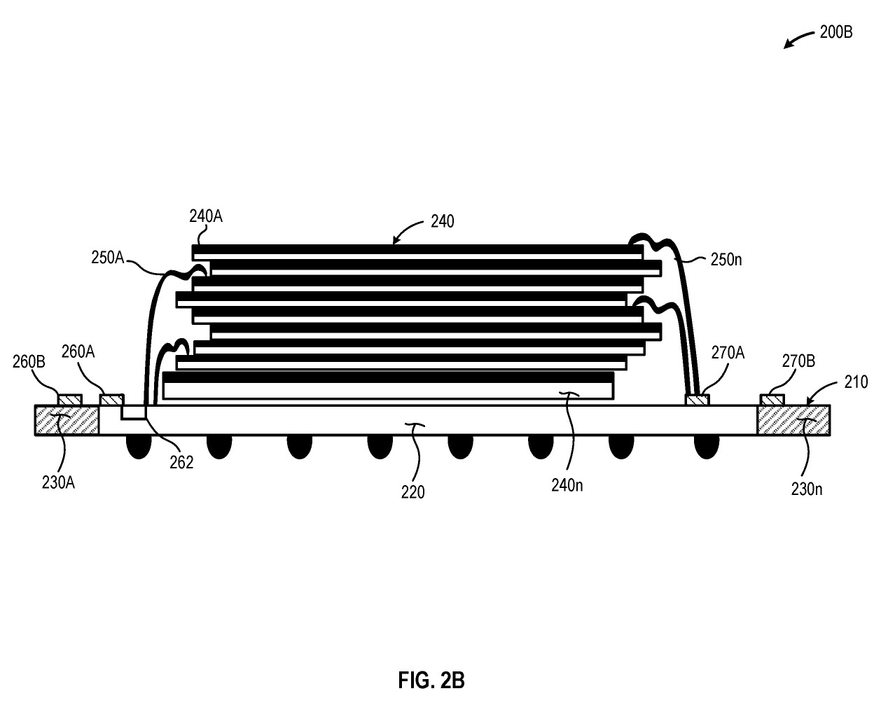

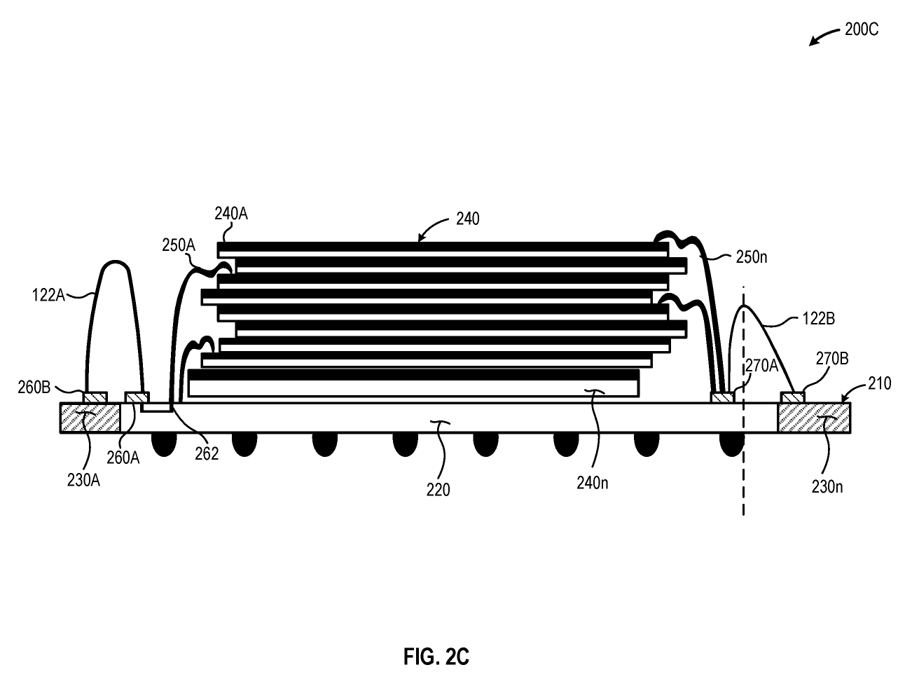

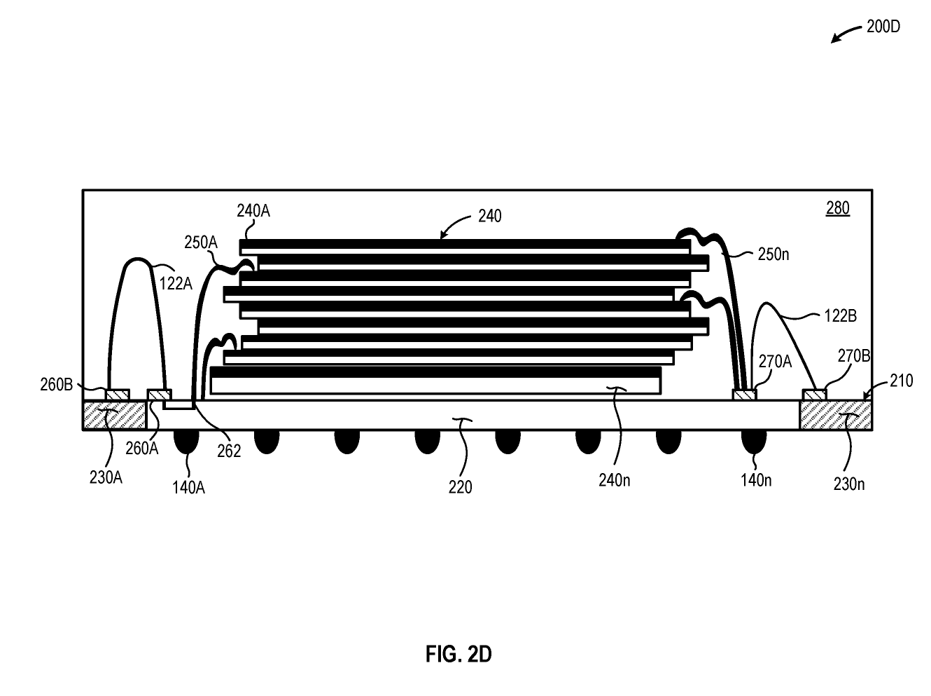

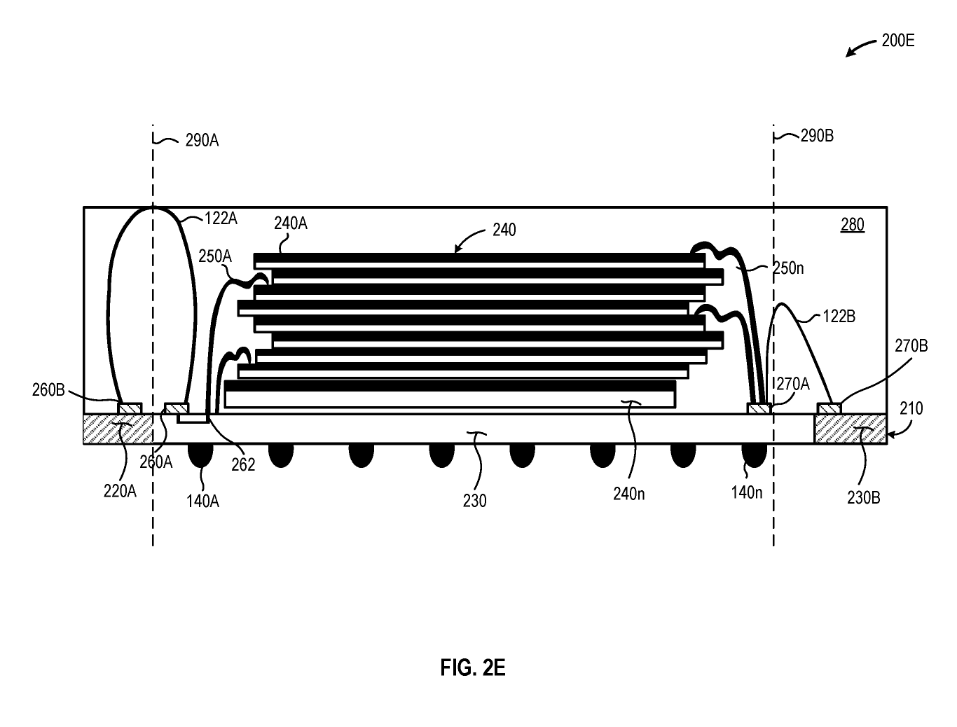

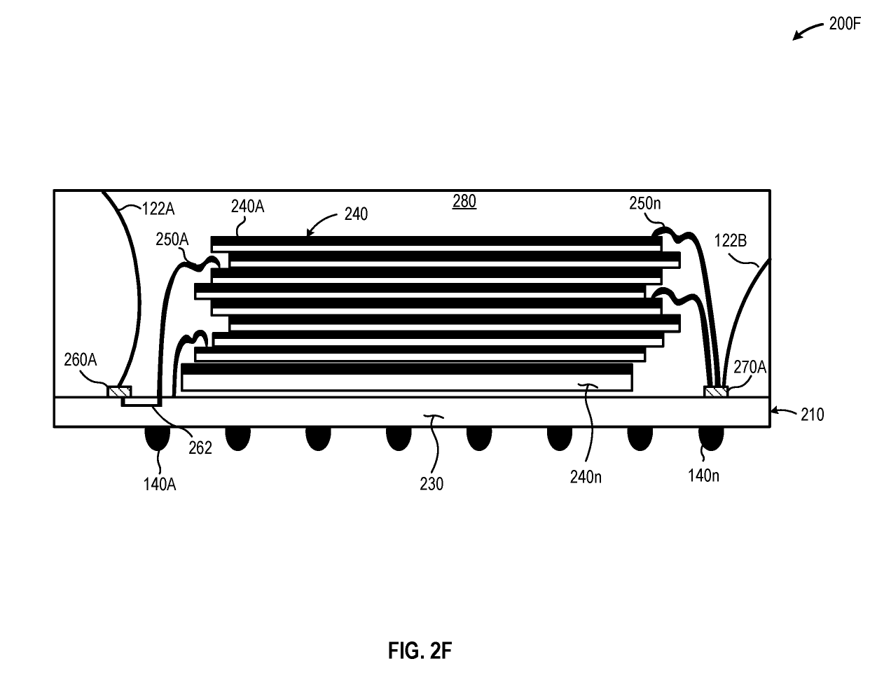

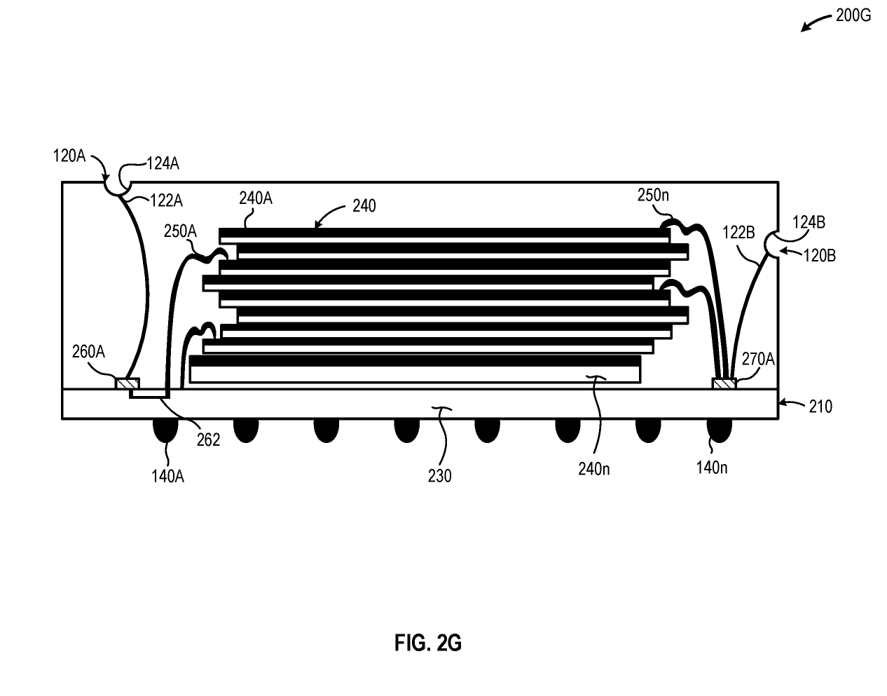

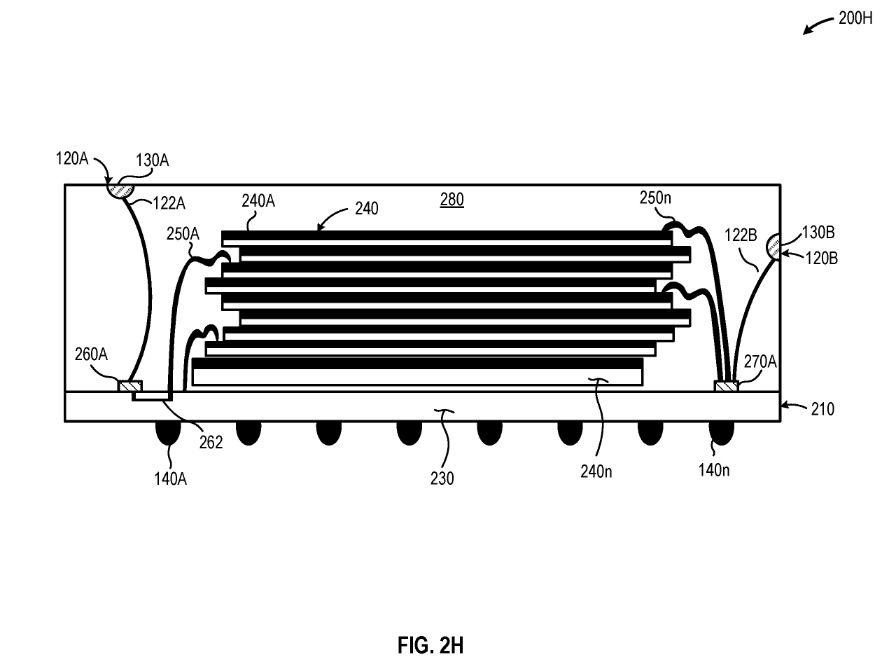

FIGS. 2A-2H are cross-sectional elevations depicting the fabrication of an illustrative semiconductor package 110 that includes one or more test wirebond connections 120, in accordance with at least one embodiment described herein. FIG. 2A is a cross-sectional elevation of an illustrative semiconductor package 110 that includes a plurality of stacked semiconductor dies 240A-240n (collectively “semiconductor die stack 240”) disposed on a semiconductor package substrate 210 that includes a first region 220 occupied by the semiconductor die stack 240 and one or more peripheral regions 230A-230n (collectively, “peripheral regions 230”), in accordance with at least one embodiment described herein. FIG. 2B is a cross sectional elevation of the illustrative semiconductor package 110 in FIG. 2A with pad stacks 260A and 270A disposed on the first portion of the upper surface of the semiconductor package substrate 210 and dummy pad stacks 260B and 270B disposed in the peripheral region of the upper surface of the semiconductor package substrate 210, in accordance with at least one embodiment described herein. FIG. 2C is a cross sectional elevation of the illustrative semiconductor package 110 in FIG. 2B with test wirebond 122A conductively coupling pad stack 260A to dummy pad stack 260B and test wirebond 122B conductively coupling pad stack 270A to dummy pad stack 270B, in accordance with at least one embodiment described herein. FIG. 2D is a cross sectional elevation of the illustrative semiconductor package 110 in FIG. 2C with a mold compound 280 disposed across the upper surface of the semiconductor package substrate 210, in accordance with at least one embodiment described herein. FIG. 2E is a cross sectional elevation of the illustrative semiconductor package 110 in FIG. 2D depicting cut lines 290A and 290B to remove the peripheral regions 220 of the semiconductor package substrate 110, in accordance with at least one embodiment described herein. FIG. 2F is a cross sectional elevation of the illustrative semiconductor package 110 in FIG. 2E after removing the peripheral regions 220 of the semiconductor package substrate 110 and exposing the test wirebonds 122A and 122B, in accordance with at least one embodiment described herein. FIG. 2G is a cross sectional elevation of the illustrative semiconductor package 110 in FIG. 2F after forming the cavities 124 about the test wirebonds 122A and 122B, in accordance with at least one embodiment described herein. FIG. 2H is a cross sectional elevation of the illustrative semiconductor package 110 in FIG. 2G after filling the cavities 124 with a filler material 130A and 130B, in accordance with at least one embodiment described herein.

Turning first to FIG. 2A, a semiconductor die stack 240 that includes a plurality of semiconductor dies 240A-240n are conductively coupled to a semiconductor package substrate 210. The semiconductor die stack 240 is disposed proximate a first portion 220 of the semiconductor package substrate 210. Wirebonds 250A-250n conductively couple at least some of the semiconductor dies 240A-240n to the first portion 220 of the upper surface of the semiconductor package substrate 210. A plurality of conductive structures 140 are disposed proximate a lower surface of the semiconductor package substrate 210. The semiconductor dies 240A-240n may include any number or combination of semiconductor dies. Example semiconductor dies 240A-240n include, but are not limited to: processors, controllers, memory, network interfaces, input/output interfaces, power management, or combinations thereof.

One or more conductive structures 262 disposed at least partially within the first portion 220 of the semiconductor package substrate 210 conductively couples wirebond 250A to pad stack 260A. The one or more conductive structures 262 may include any number and/or combination of conductive traces, vias, electronic components, and/or logic devices. In embodiments, wirebond 250n conductively couples semiconductor die 240A to a pad stack 270A disposed on the upper surface of the first portion 220 of the semiconductor package substrate 210.

In FIG. 2B, one or more dummy pad stacks 260B may be disposed, formed, patterned, or otherwise deposited on an upper surface of a peripheral region 230A of the semiconductor package substrate 210. One or more additional dummy pad stacks 270B may be disposed, formed, patterned, or otherwise deposited on an upper surface of a peripheral region 230B of the semiconductor package substrate 210.

In FIG. 2C, a test wirebond 122A conductively couples the pad stack 260A to the dummy pad stack 260B. The desired location of the test wirebond connection 120 (e.g., side of semiconductor package 110 or top of semiconductor package 110) determines the height of the test wirebond 122A. As depicted in FIG. 2C, the height of test wirebond 122A may indicate a test wirebond connection 120 disposed on the top of semiconductor package 110 or disposed high on the side of the semiconductor package 110. The one or more conductive structures 262 disposed in the semiconductor package substrate 210 conductively couples test wirebond 122A to a semiconductor die in the semiconductor die stack 240.

A second test wirebond 122B conductively couples pad stack 270A to the dummy pad stack 270B. As depicted in FIG. 2C, the height of test wirebond 122B may indicate a test wirebond connection 120 disposed on the side of the semiconductor package 110. The pad stack 270A conductively couples test wirebond 122B to a semiconductor die in the semiconductor die stack 240.

In FIG. 2D, a mold compound 280 encapsulates the semiconductor die stack 240 and extends across both the first portion 220 of the semiconductor package substrate 210 and the peripheral portions 230A-230n of the semiconductor package substrate 210. In embodiments, the mold compound may include any electrically insulative or dielectric material.

In FIG. 2E, cut lines 290A and 290B indicate the location where the peripheral regions 230A and 230B are separated from the first portion 220 of the semiconductor package substrate 210. The dummy pad stacks 260B and 270B are removed with the peripheral regions 230A and 230B of the semiconductor package substrate 210. In some embodiments, additional mold compound may be removed from the upper surface of the semiconductor package 110 to expose test wirebonds 122 on the top surface of the semiconductor package.

In FIG. 2F, the peripheral regions 230A and 230B are separated from the first region 220 of the semiconductor package substrate 210. A first portion of test wirebond 122A remains embedded in the mold compound 280 and a second portion of test wirebond 122A is exposed on the upper surface of the semiconductor package 110. A first portion of test wirebond 122B remains embedded in the mold compound 280 and a second portion of test wirebond 122B is exposed on a side of the semiconductor package 110.

In embodiments, the peripheral regions 230 may be separated from the first region 220 using any currently available or future developed cutting process. In embodiments, a saw or similar mechanical cutting device or system may be used to separate the peripheral regions 230 from the first region 220. In other embodiments, a laser or similar electromagnetic device or system may be used to separate the peripheral regions 230 from the first region 220.

In FIG. 2G, cavities 124A and 124B have been formed proximate the test wirebonds 122A and 122B to provide test wirebond connections 120A and 120B. The cavities 124 may have the same or different diameters and/or the same or different depths. In embodiments, each cavity 124 may have a diameter of: about 10 micrometers (μm) or less; about 50 μm or less; about 100 μm or less; about 250 μm or less; about 500 μm or less; about 1 millimeter (mm) or less; about 2 mm or less; or about 5 mm or less. In embodiments, each cavity 124 may have a depth of: about 10 micrometers (μm) or less; about 50 μm or less; about 100 μm or less; about 250 μm or less; about 500 μm or less; about 1 millimeter (mm) or less; about 2 mm or less; or about 5 mm or less. The cavities 124 may have any cross-sectional profile. For example, the cavities 124 may have a hemispherical cross-sectional profile or a conical cross-sectional profile.

The cavities 124 may be formed using any currently available or future developed material removal process or method. In embodiments, some or all of the cavities 124 may be formed using a drill or other mechanical material removal processes or methods. In other embodiments, some or all of the cavities 124 may be formed using laser ablation or other electromagnetic material removal processes or methods.

In FIG. 2H, a filler material 130 at least partially fills each of the cavities 124. In embodiments, the filler material 130 may include one or more dielectric or electrically non-conductive materials such as a non-conductive epoxy or polymer material. Such materials protect the test wirebonds from environmental damage and/or contamination. In other embodiments, the filler material 130 may include one or more electrically conductive materials such as a conductive polymer, a metal, or a metal alloy (e.g., solder). Using an electrically conductive filler material 130 may permit the communicable or conductive coupling of one or more external devices to the semiconductor package 110.

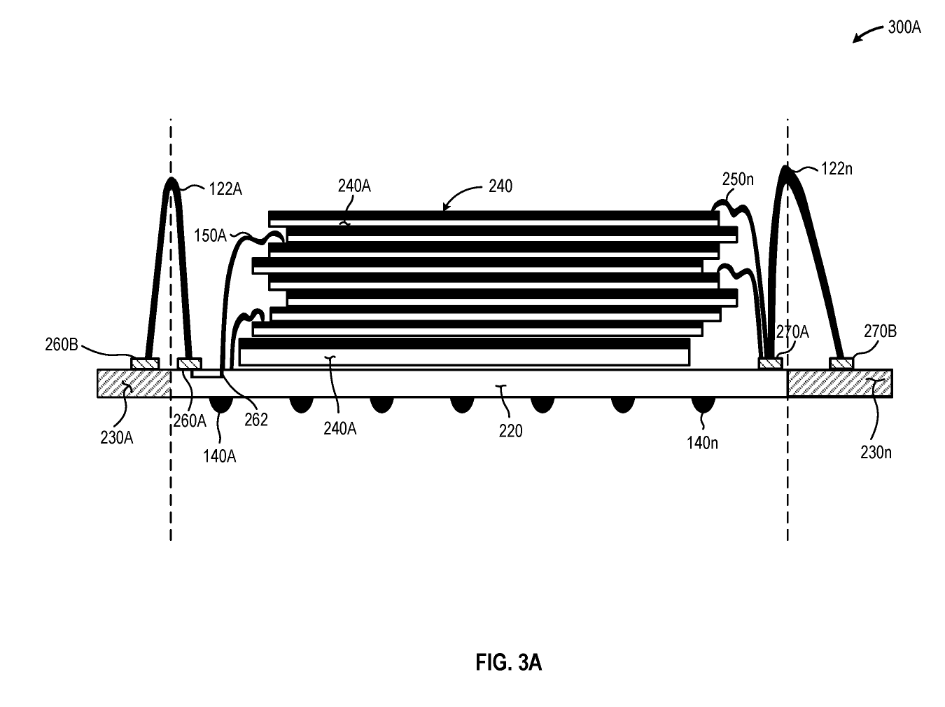

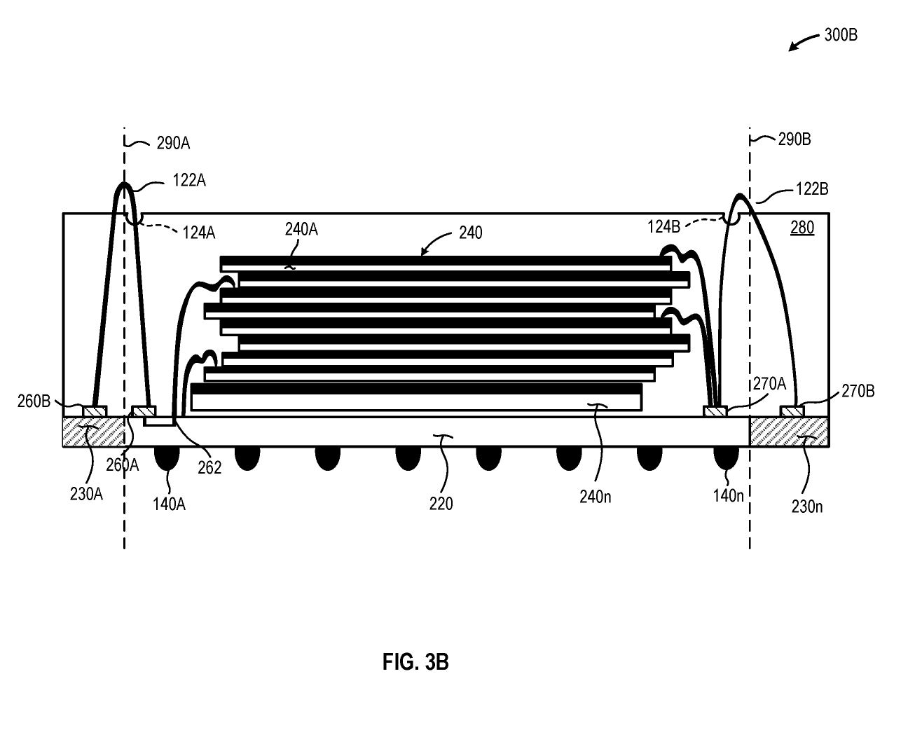

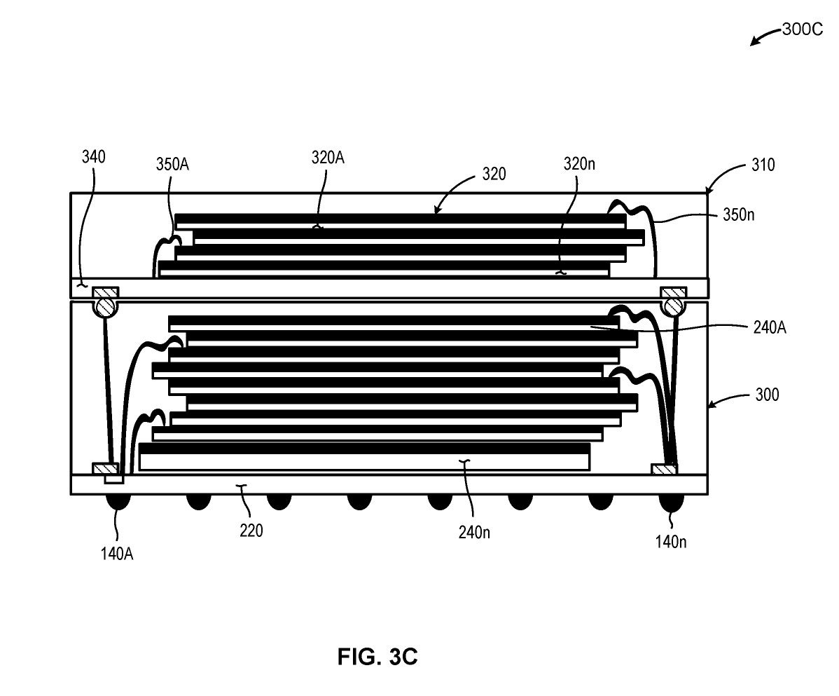

FIG. 3A is a cross-sectional elevation of an illustrative semiconductor package 300 that includes a plurality of stacked semiconductor dies disposed on a semiconductor package substrate 210 that includes a first region 220 occupied by the semiconductor die stack 240 and one or more peripheral regions 230, in accordance with at least one embodiment described herein. FIG. 3B is a cross sectional elevation of the illustrative semiconductor package 300 depicted in FIG. 3A depicting cut lines 290 and cavities 124A and 124B disposed on an upper surface of the semiconductor package 300, in accordance with at least one embodiment described herein. FIG. 3C is a cross sectional elevation of the illustrative semiconductor package 300 in FIG. 3B with test wirebond 122A and test wirebond 122B conductively coupled to a stacked second semiconductor package 310 via solder balls 302A and 302B, in accordance with at least one embodiment described herein.

Turning first to FIG. 3A, test wirebond 122A is conductively coupled between pad stack 260A and dummy pad stack 260B. Test wirebond 122A extends beyond the uppermost semiconductor die 240 included in semiconductor package 300. Test wirebond 122B is conductively coupled between pad stack 270A and dummy pad stack 270B. Test wirebond 122B also extends beyond the uppermost semiconductor die 240 included in semiconductor package 300.

Turning next to FIG. 3B, a mold compound 280 has been disposed about die stack 240. Test wirebond 122A and test wirebond 122B extend beyond the upper surface of the mold compound 280. Cavities 124 (depicted as dashed lines in FIG. 3B) will be formed in the upper surface of the semiconductor package 300 about the test wirebonds 122A and 122B.

Turning to FIG. 3C, a second semiconductor package 310 is physically and conductively coupled to the semiconductor package 300 using conductive structures 302A and 302B (collectively, “conductive structures 302”) disposed in cavities 124A and 124B. The second semiconductor package 310 may include a die stack 320 that includes a plurality of semiconductor dies 320A-320n physically and conductively coupled to a semiconductor package substrate 340. A plurality of wirebonds 350A-350n may conductively couple at least some of the semiconductor dies 320A-320n to the semiconductor package substrate 340. In embodiments, the conductive structures 302A and 302B may physically and conductively couple the second portion of test wirebonds 122A and 122B to contact pads 330A and 330B disposed on the lower surface of the second semiconductor package 310. The conductive structures 302 may include any electrically conductive device or system. In at least one embodiment, the conductive structures 302 may include solder bumps or solder balls.

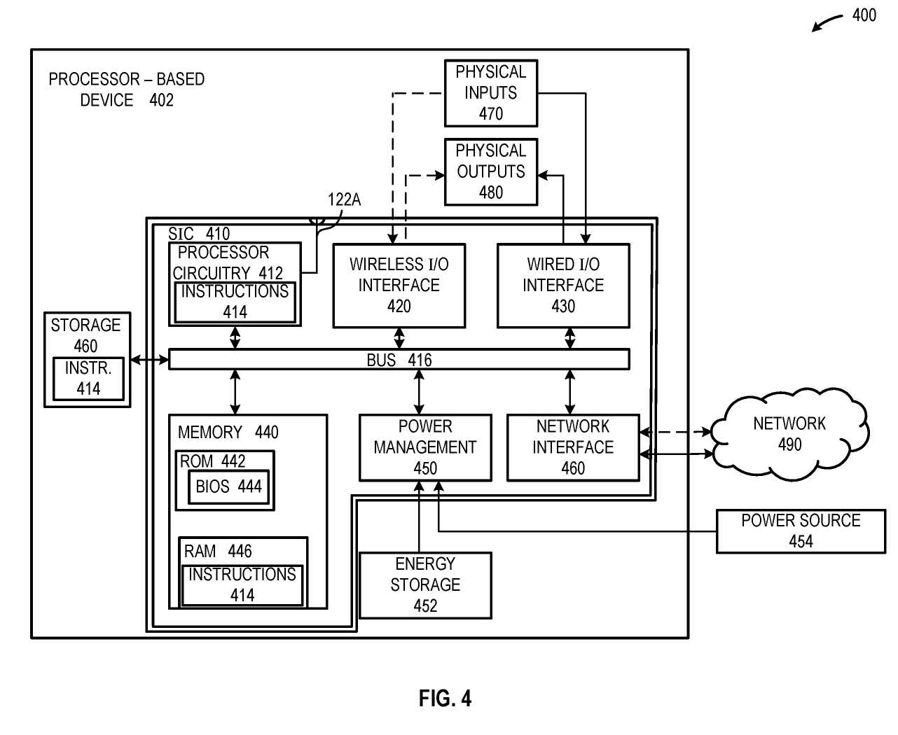

FIG. 4 is a schematic diagram of an illustrative processor-based device 400 that includes a system-in-chip 410 having test wirebonds, as described in FIGS. 1 through 3 and in accordance with at least one embodiment described herein. The following discussion provides a brief, general description of the components forming the illustrative processor-based device 400 such as a smartphone, wearable computing device, portable computing device, or any similar device having at least one semiconductor package that includes test wirebonds 122A and 122B. In embodiments, the test wirebonds 122A and 122B may provide the capability for conductively coupling the semiconductor package to an external device either during or after the manufacturing process. In other embodiments, the test wirebonds 122 may conductively couple stacked semiconductor packages (not depicted in FIG. 4).

The processor-based device 400 includes processor circuitry 412 capable of executing machine-readable instruction sets 414, reading data and/or instructions 414 from a storage device 460 and writing data to the storage device 460. Those skilled in the relevant art will appreciate that the illustrated embodiments as well as other embodiments can be practiced with other circuit-based device configurations, including portable electronic or handheld electronic devices, for instance smartphones, portable computers, wearable computers, microprocessor-based or programmable consumer electronics, personal computers (“PCs”), network PCs, minicomputers, mainframe computers, and the like.

The processor circuitry 412 may include any number of hardwired or configurable circuits, some or all of which may include programmable and/or configurable combinations of electronic components, semiconductor devices, and/or logic elements that are disposed partially or wholly in a PC, server, or other computing system capable of executing machine-readable instructions.

The processor-based device 400 includes a bus or similar communications link 416 that communicably couples and facilitates the exchange of information and/or data between various system components including a system memory 440, one or more data storage devices 460, and/or one or more network interfaces 460. The processor-based device 400 may be referred to in the singular herein, but this is not intended to limit the embodiments to a single device and/or system, since in certain embodiments, there will be more than one processor-based device 400 that incorporates, includes, or contains any number of communicably coupled, collocated, or remote networked circuits or devices.

The processor circuitry 412 may include any number, type, or combination of devices. At times, the processor circuitry 412 may be implemented in whole or in part in the form of semiconductor devices such as diodes, transistors, inductors, capacitors, and resistors. Such an implementation may include, but is not limited to any current or future developed single- or multi-core processor or microprocessor, such as: on or more systems on a chip (SOCs); central processing units (CPUs); digital signal processors (DSPs); graphics processing units (GPUs); application-specific integrated circuits (ASICs), programmable logic units, field programmable gate arrays (FPGAs), and the like. Unless described otherwise, the construction and operation of the various blocks shown in FIG. 4 are of conventional design. Consequently, such blocks need not be described in further detail herein, as they will be understood by those skilled in the relevant art. The communications link 416 that interconnects at least some of the components of the processor-based device 400 may employ any known serial or parallel bus structures or architectures.

The processor-based device 400 may include one or more wireless input/output (I/O) interfaces 420. In embodiments, the wireless I/O interfaces 420 may communicably couple to one or more physical input devices 470 (pointing devices, touchscreens, keyboards, tactile devices, etc.) and/or one or more physical output devices 480 (display devices, hardcopy devices, tactile output devices, audio devices, etc.). The wireless I/O interface 420 may include any currently available or future developed I/O interface. The semiconductor die that includes the wireless I/O interface 420 may be disposed in the SiC 410 die stack.

The processor-based device 400 may include one or more wired input/output (I/O) interfaces 430. In embodiments, the wired I/O interfaces 430 may communicably couple to one or more physical input devices 470 (pointing devices, touchscreens, keyboards, tactile devices, etc.) and/or one or more physical output devices 480 (display devices, hardcopy devices, tactile output devices, audio devices, etc.). The wired I/O interface 430 may include any currently available or future developed I/O interface. The semiconductor die that includes the wired I/O interface 430 may be disposed in the SiC 410 die stack.

The system memory 440 may include read-only memory (“ROM”) 442 and random access memory (“RAM”) 446. A portion of the ROM 442 may be used to store or otherwise retain a basic input/output system (“BIOS”) 444. The BIOS 444 provides basic functionality to the processor-based device 400, for example by causing the processor circuitry 412 to load one or more machine-readable instruction sets 414. In embodiments, at least some of the one or more machine-readable instruction sets 414 cause at least a portion of the processor circuitry 412 to provide, create, produce, transition, and/or function as a dedicated, specific, and particular machine, for example a word processing machine, a digital image acquisition machine, a media playing machine, a gaming system, a communications device, or similar.

The processor-based device 400 may include one or more communicably coupled, non-transitory, data storage devices 460. Such storage devices 460 may include one or more hard disk drives and/or one or more solid-state storage devices. The one or more data storage devices 460 may include any current or future developed storage appliances, network storage devices, and/or systems. Non-limiting examples of such data storage devices 460 may include, but are not limited to, any current or future developed non-transitory storage appliances or devices, such as one or more magnetic storage devices, one or more optical storage devices, one or more electro-resistive storage devices, one or more molecular storage devices, one or more quantum storage devices, or various combinations thereof. In some implementations, the one or more data storage devices 460 may include one or more removable storage devices, such as one or more flash drives, flash memories, flash storage units, or similar appliances or devices capable of communicable coupling to and decoupling from the processor-based device 400.

The one or more data storage devices 460 may include interfaces or controllers (not shown) communicatively coupling the respective storage device or system to the communications link 416. The one or more data storage devices 460 may store, retain, or otherwise contain machine-readable instruction sets, data structures, program modules, data stores, databases, logical structures, and/or other data useful to the processor circuitry 412 and/or one or more applications executed on or by the processor circuitry 412. In some instances, one or more data storage devices 460 may be communicably coupled to the processor circuitry 412, for example via communications link 416 or via one or more wired communications interfaces 430 (e.g., Universal Serial Bus or USB); one or more wireless communications interfaces 420 (e.g., Bluetooth®, Near Field Communication or NFC); and/or one or more network interfaces 460 (IEEE 802.3 or Ethernet, IEEE 802.11, or WiFi®, etc.).

Machine-readable instruction sets 414 and other programs, applications, logic sets, and/or modules may be stored in whole or in part in the system memory 440. Such instruction sets 414 may be transferred, in whole or in part, from the one or more data storage devices 460. The instruction sets 414 may be loaded, stored, or otherwise retained in system memory 440, in whole or in part, during execution by the processor circuitry 412. The machine-readable instruction sets 414 may include machine-readable and/or processor-readable code, instructions, or similar logic capable of providing the speech coaching functions and capabilities described herein.

The processor-based device 400 may include power management circuitry 450 that controls one or more operational aspects of the energy storage device 452. In embodiments, the energy storage device 452 may include one or more primary (i.e., non-rechargeable) or secondary (i.e., rechargeable) batteries or similar energy storage devices. In embodiments, the energy storage device 452 may include one or more supercapacitors or ultracapacitors. In embodiments, the power management circuitry 450 may alter, adjust, or control the flow of energy from an external power source 454 to the energy storage device 452 and/or to the processor-based device 400. The power source 454 may include, but is not limited to, a solar power system, a commercial electric grid, a portable generator, an external energy storage device, or any combination thereof.

For convenience, a network interface 460, the processor circuitry 412, the wireless I/O interface 420, the wired I/O interface 430, the system memory 440, the power management circuitry 450, and the network interface 460 are illustrated as communicatively coupled to each other via the communications link 416, thereby providing connectivity between the above-described components. In alternative embodiments, the above-described components may be communicatively coupled in a different manner than illustrated in FIG. 4. For example, one or more of the above-described components may be directly coupled to other components, or may be coupled to each other, via one or more intermediary components (not shown). In some embodiments, all or a portion of the communications link 416 may be omitted and the components are coupled directly to each other using suitable wired or wireless connections.

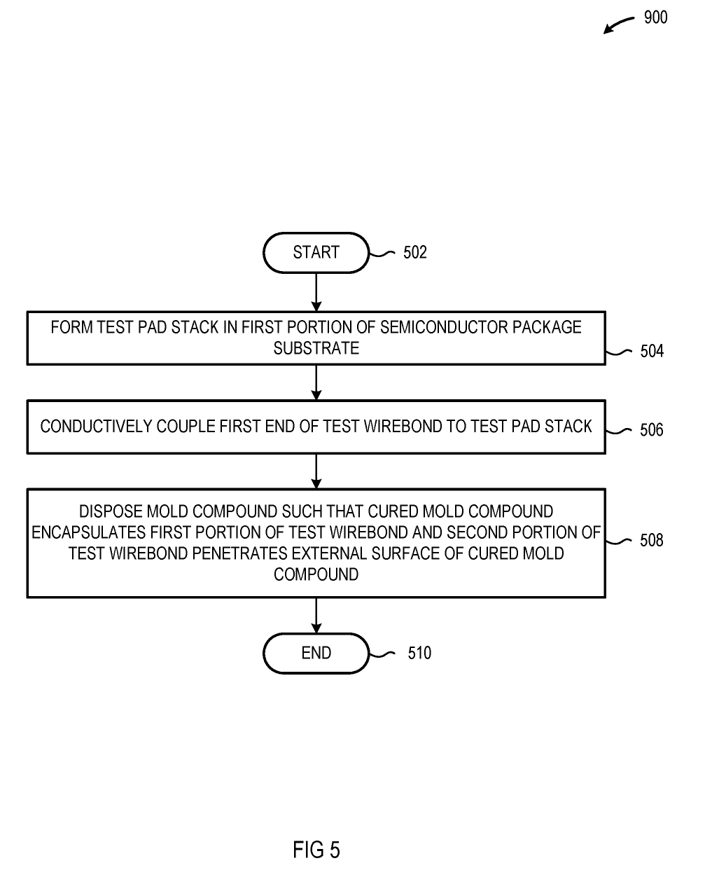

FIG. 5 is a high-level flow diagram of an illustrative method 500 of fabricating a semiconductor package having at least one externally accessible test wirebond 122, in accordance with at least one embodiment described herein. The externally accessible wirebonds 122 beneficially and advantageously provides the capability to conductively couple external equipment, such as test equipment to a semiconductor package 110, or even a specific semiconductor die 240 within a semiconductor package 110, after the package has been affixed to a substrate 150. In embodiments, a first end of a test wirebond 122 conductively couples to a test pad stack 260A, 270A in a first region 220 of a semiconductor package substrate 210 and a second end of the test wirebond conductively couples to a dummy pad stack 260B, 270B in a peripheral region 230 of the semiconductor package substrate 210. After disposing a mold compound 280 about the semiconductor package substrate 210, the peripheral regions 230 of the semiconductor package substrate 210 are trimmed, severing the test wirebond 122 and exposing the wirebond on the surface of the semiconductor package 110. The method 500 commences at 502.

At 504, a test pad stack 260A, 270A is patterned, deposited, formed, or otherwise disposed on a first region 220 on the upper surface of a semiconductor package substrate 210. In embodiments, the first region 220 of the upper surface of the semiconductor package substrate 210 may include the portion of the semiconductor package substrate 210 occupied by the semiconductor die stack 240. In embodiments, the test pad stack 260A, 270A may conductively couple to one or more circuits or similar conductive structures formed or disposed at least partially within the semiconductor package substrate 210. In embodiments, the test pad stack 260A, 270A may directly conductively couple (i.e., without any intervening electronic or semiconductor components) to a contact pad or similar conductive structure disposed in, on, or about a portion of the lower surface of the semiconductor package substrate 210. In embodiments, the test pad stack 260A, 270A may indirectly conductively couple (i.e., through one or more intervening electronic or semiconductor components) to a contact pad or similar conductive structure disposed in, on, or about a portion of the lower surface of the semiconductor package substrate 210.

At 506, a first end of a test wirebond 122A, 122B is conductively coupled to the test pad stack 260A, 270A. The first end of the wirebond 122A, 122B may be conductively coupled to the test pad stack 260A, 270A using any currently available or future developed method or process for forming an electrically conductive bond between the test wirebond and the test pad stack 260A, 270A. For example, the first end of the test wirebond 122A, 122B may be conductively coupled to the test pad stack 260A, 270A using reflowed solder to form an electrically conductive bond between the test wirebond and the test pad stack 260A, 270A.

At 508, a mold compound 280 is disposed about a first portion of the test wirebond 122. A second portion of the test wirebond 122 penetrates the surface of the mold compound 280 and remains exposed. The mold compound 280 may be disposed about the test wirebond 122 using any currently available or future developed material deposition process or method. For example, the mold compound 280 may include one or more curable liquid compounds that may be flowed about the semiconductor die stack 240 and test wirebonds 122 and cured to form a resilient semiconductor package 110. The method 500 concludes at 510.

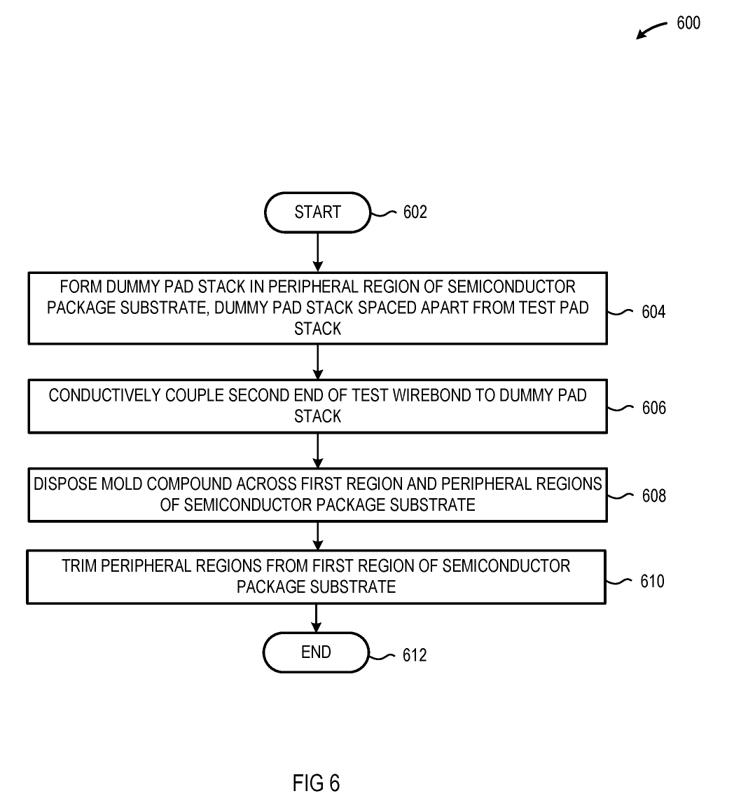

FIG. 6 is a high-level flow diagram of an illustrative method 600 of fabricating a semiconductor package 110 having at least one externally accessible test wirebond 122, in accordance with at least one embodiment described herein. The method 600 may be used in conjunction with the method 500 discussed above with regard to FIG. 5. The method 600 commences at 602.

At 604, a dummy pad stack 260B, 270B is patterned, deposited, formed, or otherwise disposed on a peripheral region 230 of the upper surface of the semiconductor package substrate 210. In embodiments, the peripheral regions 230 of the upper surface of the semiconductor package substrate 210 may include portions of the semiconductor package substrate 210 not occupied by the semiconductor die stack 240, such as the region about the periphery of the semiconductor die stack 240. In embodiments, the dummy pad stack 260B, 270B may be electrically isolated from circuits or similar conductive structures formed or disposed at least partially within the semiconductor package substrate 210.

At 606, the second end of the test wirebond 122 is conductively coupled to the dummy pad stack 260B, 270B. The second end of the wirebond 122A, 122B may be conductively coupled to the dummy pad stack 260B, 270B using any currently available or future developed method or process for forming an electrically conductive bond between the test wirebond and the dummy pad stack 260B, 270B. For example, the second end of the test wirebond 122A, 122B may be conductively coupled to the dummy pad stack 260B, 270B using reflowed solder to form an electrically conductive bond between the test wirebond and the dummy pad stack 260B, 270B.

At 608, mold compound 280 is disposed about the die stack 240 and the test wirebonds 122A, 122B. The mold compound 280 extends across the first region of the upper surface of the semiconductor package substrate 210 and the peripheral regions of the upper surface of the semiconductor package substrate 210. The mold compound 280 is disposed about a first portion of the test wirebonds 122A, 122B. A second portion of the test wirebonds 122A, 122B penetrates the mold compound 280 and remains exposed.

At 610, the peripheral regions 230 of the semiconductor package substrate 210 are trimmed away. The peripheral regions 230 may be separated or trimmed from the first region 22 of the semiconductor package substrate 210 using any currently available or future developed cutting process or method. For example, the peripheral regions 230 may be separated from the first region 220 using a saw or similar mechanical, and/or abrasive cutting process. The method 600 concludes at 612.

While FIGS. 5 and 6 illustrate various operations according to one or more embodiments, it is to be understood that not all of the operations depicted in FIGS. 5 and 6 are necessary for other embodiments. Indeed, it is fully contemplated herein that in other embodiments of the present disclosure, the operations depicted in FIGS. 5 and 6, and/or other operations described herein, may be combined in a manner not specifically shown in any of the drawings, but still fully consistent with the present disclosure. Thus, claims directed to features and/or operations that are not exactly shown in one drawing are deemed within the scope and content of the present disclosure.

As used in this application and in the claims, a list of items joined by the term “and/or” can mean any combination of the listed items. For example, the phrase “A, B and/or C” can mean A; B; C; A and B; A and C; B and C; or A, B and C. As used in this application and in the claims, a list of items joined by the term “at least one of” can mean any combination of the listed terms. For example, the phrases “at least one of A, B or C” can mean A; B; C; A and B; A and C; B and C; or A, B and C.

Any of the operations described herein may be implemented in a system that includes one or more mediums (e.g., non-transitory storage mediums) having stored therein, individually or in combination, instructions that when executed by one or more processors perform the methods. Here, the processor may include, for example, a server CPU, a mobile device CPU, and/or other programmable circuitry. Also, it is intended that operations described herein may be distributed across a plurality of physical devices, such as processing structures at more than one different physical location. The storage medium may include any type of tangible medium, for example, any type of disk including hard disks, floppy disks, optical disks, compact disk read-only memories (CD-ROMs), rewritable compact disks (CD-RWs), and magneto-optical disks, semiconductor devices such as read-only memories (ROMs), random access memories (RAMs) such as dynamic and static RAMs, erasable programmable read-only memories (EPROMs), electrically erasable programmable read-only memories (EEPROMs), flash memories, Solid State Disks (SSDs), embedded multimedia cards (eMMCs), secure digital input/output (SDIO) cards, magnetic or optical cards, or any type of media suitable for storing electronic instructions. Other embodiments may be implemented as software executed by a programmable control device.

Thus, the present disclosure is directed to systems and methods of accessing semiconductor die in a semiconductor package coupled to a substrate using one or more externally accessible test wirebonds. In embodiments, a test pad stack may be disposed in a first region of an upper surface of a semiconductor package substrate. One or more semiconductor dies may be conductively coupled to the test pad stack. A first end of a test wirebond may be conductively coupled to the test pad stack. A dummy pad stack may be disposed in a peripheral region on the upper surface of the semiconductor package substrate. A second end of the test wirebond may be conductively coupled to the dummy pad stack. A mold compound may be disposed on, about, or across the first region and the peripheral regions of the upper surface of the semiconductor package substrate. A first portion of the test wirebond may be disposed in the cured mold compound. The peripheral regions may be trimmed from the semiconductor package substrate, exposing at least a second portion of the test wirebond.

The following examples pertain to further embodiments. The following examples of the present disclosure may comprise subject material such as at least one device, a method, at least one machine-readable medium for storing instructions that when executed cause a machine to perform acts based on the method, means for performing acts based on the method and/or a system for providing an externally accessible test wirebond in a semiconductor package mounted on a substrate.

According to example 1, there is provided a semiconductor package. The semiconductor package may include: a semiconductor package substrate having an upper surface and a lower surface, the semiconductor package substrate including at least one test pad stack disposed on the upper surface; at least one test wirebond communicably coupled to the at least one test pad stack; and mold compound disposed proximate the upper surface of the semiconductor package substrate, a first portion of the at least one test wirebond encapsulated by the mold compound and a second portion of the at least one test wirebond penetrates an exterior surface of the mold compound.

Example 2 may include elements of example 1, and the semiconductor package may additionally include: at least one semiconductor die communicably coupled to the at least one test pad stack such that the test wirebond communicably couples to the at least one semiconductor die.

Example 3 may include elements of any of examples 1 or 2 where a wirebond communicably couples the at least one semiconductor die to the at least one test pad stack.

Example 4 may include elements of any of examples 1 through 3 where the semiconductor package substrate includes one or more conductive structures to communicably couple the at least one semiconductor die to the at least one test pad stack.

Example 5 may include elements of any of examples 1 through 4 where the semiconductor package substrate further comprises: a plurality of contact pads disposed on the lower surface of the semiconductor package substrate.

Example 6 may include elements of any of examples 1 through 5, and the semiconductor package may additionally include: a plurality electrically conductive members, each of the plurality of electrically conductive members conductively coupled to a respective one of at least a portion of the plurality of contact pads.

Example 7 may include elements of any of examples 1 through 6 where the at least one semiconductor die comprises a plurality of semiconductor dies.

Example 8 may include elements of any of examples 1 through 7 where the plurality of semiconductor dies and the semiconductor package comprises a system-in-package.

Example 9 may include elements of any of examples 1 through 8 where the mold compound further comprises a cavity disposed proximate the at least one test wirebond such that the test wirebond is exposed within the cavity.

Example 10 may include elements of any of examples 1 through 9, and the semiconductor package may additionally include: an electrically non-conductive material at least partially filling the cavity.

Example 11 may include elements of any of examples 1 through 10, and the semiconductor package may additionally include: a conductive material disposed at least partially in the cavity.

According to example 12, there is provided a semiconductor package fabrication method. The method may include: forming at least one test pad stack on an upper surface of a semiconductor package substrate; conductively coupling a first end of at least one test wirebond to the at least one test pad stack; and disposing a mold compound proximate the upper surface of the semiconductor package substrate, such that the mold compound encapsulates a first portion of the at least one test wirebond and a second portion of the at least one test wirebond penetrates an exterior surface of the mold compound.

Example 13 may include elements of example 13 where the semiconductor package comprises an oversize semiconductor package substrate having a first region occupied by the semiconductor package and at least one peripheral region; and where the at least one test pad stack is disposed in the first region.

Example 14 may include elements of any of examples 12 or 13, and the method may additionally include: forming at least one dummy pad stack spaced apart from the at least one test pad stack the at least one dummy pad stack disposed on the upper surface of the at least one peripheral region of the semiconductor package substrate; conductively coupling a second end of the at least one test wirebond to the at least one dummy pad stack; disposing the mold compound proximate the upper surface of the semiconductor package substrate including the first region and the at least one peripheral region; and cutting the at least one peripheral region and the mold compound disposed proximate the at least one peripheral region to separate the at least one peripheral region of semiconductor package substrate from the first region of the semiconductor package substrate.

Example 15 may include elements of any of examples 12 through 14, and the method may additionally include: conductively coupling at least one semiconductor die to the upper surface of the semiconductor package substrate; and conductively coupling the at least one semiconductor die to the at least one test pad stack.

Example 16 may include elements of any of examples 12 through 15 where conductively coupling the semiconductor die to the at least one test pad stack may include: conductively coupling the semiconductor die to the at least one test pad stack via one or more conductive structures disposed in the semiconductor package substrate.

Example 17 may include elements of any of examples 12 through 16 where conductively coupling the semiconductor die to the at least one test pad stack may include: conductively coupling the semiconductor die to the at least one test pad stack via one or wirebonds.

Example 18 may include elements of any of examples 12 through 17 where conductively coupling at least one semiconductor die to the upper surface of the semiconductor package substrate may include: conductively coupling a plurality of semiconductor dies to the upper surface of the semiconductor package substrate.

Example 19 may include elements of any of examples 12 through 18 where conductively coupling a plurality of semiconductor dies to the upper surface of the semiconductor package substrate may include: conductively coupling a plurality of semiconductor dies to the upper surface of the semiconductor package substrate, the plurality of semiconductor dies forming a system-in-package.

Example 20 may include elements of any of examples 12 through 19, and the method may additionally include: forming a cavity in the mold compound proximate the second portion of the at least one test wirebond.

Example 21 may include elements of any of examples 12 through 20, and the method may additionally include: filling the cavity in the mold compound proximate the second portion of the at least one test wirebond with an electrically non-conductive material.

Example 22 may include elements of any of examples 12 through 21, and the method may additionally include: filling the cavity in the mold compound proximate the second portion of the at least one test wirebond with an electrically conductive material.

Example 23 may include elements of any of examples 12 through 22, and the method may additionally include: conductively coupling a semiconductor die to the electrically conductive material filling the cavity in the mold compound.

According to example 24, there is provided a semiconductor package fabrication system. The system may include: means for forming at least one test pad stack on an upper surface of a semiconductor package substrate; means for conductively coupling at least one test wirebond to the at least one test pad stack; and means for disposing a mold compound proximate the upper surface of the semiconductor package substrate, such that the mold compound encapsulates a first portion of the at least one test wirebond and a second portion of the at least one test wirebond penetrates an exterior surface of the mold compound.

Example 25 may include elements of example 24 where the means for forming at least one test pad stack on an upper surface of a semiconductor package substrate may include: means for forming the at least one test pad stack in a first region of the upper surface of an oversize semiconductor package substrate; wherein the semiconductor package occupies the first region of the semiconductor package substrate and wherein the semiconductor package substrate includes at least one peripheral region separate from the first region.

Example 26 may include elements of any of examples 24 or 25, and the system may further include: means for forming at least one dummy pad stack spaced apart from the at least one test pad stack on the upper surface of the at least one peripheral region of the semiconductor package substrate; means for conductively coupling a second end of the at least one test wirebond to the at least one dummy pad stack; means for disposing the mold compound proximate the upper surface of the semiconductor package substrate including the first region and the at least one peripheral region; and means for cutting the at least one peripheral region and the mold compound disposed proximate the at least one peripheral region to separate the at least one peripheral region of semiconductor package substrate from the first region of the semiconductor package substrate.

Example 27 may include elements of any of examples 24 through 26, and the system may additionally include: means for conductively coupling at least one semiconductor die to the upper surface of the semiconductor package substrate; and conductively coupling the at least one semiconductor die to the at least one test bond pad.

Example 28 may include elements of any of examples 24 through 27 where the means for conductively coupling the semiconductor die to the at least one test pad stack may include: means for conductively coupling the semiconductor die to the at least one test pad stack via one or more conductive structures disposed in the semiconductor package substrate.

Example 29 may include elements of any of examples 24 through 28 where the means for conductively coupling the semiconductor die to the at least one test pad stack may include: means for conductively coupling the semiconductor die to the at least one test pad stack via one or wirebonds.

Example 30 may include elements of any of examples 24 through 29 where the means for conductively coupling at least one semiconductor die to the upper surface of the semiconductor package substrate may include: means for conductively coupling a plurality of semiconductor dies to the upper surface of the semiconductor package substrate.

Example 31 may include elements of any of examples 24 through 30 where the means for conductively coupling a plurality of semiconductor dies to the upper surface of the semiconductor package substrate may include: means for conductively coupling a plurality of semiconductor dies to the upper surface of the semiconductor package substrate, the plurality of semiconductor dies forming a system-in-package.

Example 32 may include elements of any of examples 24 through 31, and the system may additionally include: means for forming a cavity in the mold compound proximate the second portion of the at least one test wirebond.

Example 33 may include elements of any of examples 24 through 32, and the system may additionally include: means for filling the cavity in the mold compound proximate the second portion of the at least one test wirebond with an electrically non-conductive material.

Example 34 may include elements of any of examples 24 through 33, and the system may additionally include: means for filling the cavity in the mold compound proximate the second portion of the at least one test wirebond with an electrically conductive material.

Example 35 may include elements of any of examples 24 through 34, and the system may additionally include: means for conductively coupling a semiconductor die to the electrically conductive material filling the cavity in the mold compound.

According to example 36, there is provided an electronic device. The electronic device may include: a substrate; an semiconductor package operably coupled to the substrate, the semiconductor package including: a semiconductor package substrate having an upper surface and a lower surface, the semiconductor package substrate including at least one test pad stack disposed on the upper surface; at least one test wirebond communicably coupled to the at least one test pad stack; and mold compound disposed proximate the upper surface of the semiconductor package substrate, a first portion of the at least one test wirebond encapsulated by the mold compound and a second portion of the at least one test wirebond penetrates an exterior surface of the mold compound.

Example 37 may include elements of example 36, and the electronic device may additionally include: at least one semiconductor die communicably coupled to the at least one test pad stack such that the test wirebond communicably couples to the at least one semiconductor die.

Example 38 may include elements of any of examples 36 or 37 where a wirebond communicably couples the at least one semiconductor die to the at least one test pad stack.

Example 39 may include elements of any of examples 36 through 38 where the semiconductor package substrate includes one or more conductive structures to communicably couple the at least one semiconductor die to the at least one test pad stack.

Example 40 may include elements of any of examples 36 through 39 where the semiconductor package substrate further comprises: a plurality of contact pads disposed on the lower surface of the semiconductor package substrate.

Example 41 may include elements of any of examples 36 through 40 where the semiconductor package further comprise: a plurality electrically conductive members, each of the plurality of electrically conductive members conductively coupled to a respective one of at least a portion of the plurality of contact pads.

Example 42 may include elements of any of examples 36 through 41 where the at least one semiconductor die comprises a plurality of semiconductor dies.

Example 43 may include elements of any of examples 36 through 42 where the plurality of semiconductor dies and the semiconductor package comprises a system-in-package.

Example 44 may include elements of any of examples 36 through 43 where the mold compound further comprises a cavity disposed proximate the at least one test wirebond such that the test wirebond is exposed within the cavity.

Example 45 may include elements of any of examples 36 through 44 where the semiconductor package further comprises an electrically non-conductive material at least partially filling the cavity.

Example 46 may include elements of any of examples 36 through 45 where the semiconductor package further comprises an electrically conductive material at least partially filling the cavity.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Accordingly, the claims are intended to cover all such equivalents.

1. A semiconductor package comprising:
a semiconductor package substrate having an upper surface and a lower surface, the semiconductor package substrate including at least one test pad stack disposed on the upper surface;
at least one semiconductor die communicatively coupled to the at least one test pad stack via a first wirebond;
at least one test wirebond that is distinct and separate from the first wirebond and communicatively coupled to the at least one test pad stack; and
mold compound that is disposed proximate the upper surface of the semiconductor package substrate and that encapsulates the first wirebond, such that a first portion of the at least one test wirebond is encapsulated by the mold compound and a second portion of the at least one test wirebond penetrates an exterior surface of the mold compound.

2. (canceled)

3. (canceled)

4. The semiconductor package of claim 1 wherein the semiconductor package substrate includes one or more conductive structures to communicatively couple the at least one semiconductor die to the at least one test pad stack.

5. The semiconductor package of claim 1 wherein the semiconductor package substrate further comprises a plurality of contact pads disposed on the lower surface of the semiconductor package substrate.

6. The semiconductor package of claim 5, further comprising a plurality of electrically conductive members, each of the plurality of electrically conductive members conductively coupled to a respective one of at least a portion of the plurality of contact pads.

7. The semiconductor package of claim 1 wherein the at least one semiconductor die comprises a plurality of semiconductor dies.

8. The semiconductor package of claim 7 wherein the plurality of semiconductor dies and the semiconductor package comprises a system-in-package.

9. The semiconductor package of claim 1 wherein the mold compound further comprises a cavity disposed proximate the at least one test wirebond such that the test wirebond is exposed within the cavity.

10. The semiconductor package of claim 9, further comprising an electrically non-conductive material at least partially filling the cavity.

11. The semiconductor package of claim 9, further comprising a conductive material disposed at least partially in the cavity.

12-24. (canceled)

25. An electronic device comprising:
a substrate;
a semiconductor package operably coupled to the substrate, the semiconductor package including:
a semiconductor package substrate having an upper surface and a lower surface, the semiconductor package substrate including at least one test pad stack disposed on the upper surface;
at least one semiconductor die communicatively coupled to the at least one test pad stack via a first wirebond;
at least one test wirebond that is distinct and separate from the first wirebond and communicatively coupled to the at least one test pad stack; and
mold compound that is disposed proximate the upper surface of the semiconductor package substrate and that encapsulates the first wirebond, such that a first portion of the at least one test wirebond is encapsulated by the mold compound and a second portion of the at least one test wirebond penetrates an exterior surface of the mold compound.
